(19) United States
(12) Patent Application Publication
(10) Pub. No.: US 2019/0181878 A1
(43) Pub. Date: Jun. 13, 2019

(54) DELTA-SIGMA CONVERTER WITH PM/FM NON-LINEAR LOOP

(71) Applicant: Fundacio Centre Tecnologic de Telecomunicacions de Catalunya, Castelldefels (ES)

(72) Inventors: José RUBIO FERNÁNDEZ, Castelldefels (ES); Ana Isable PÉREZ NEIRA, Castelldefels (ES); Miguel Angel LAGUNAS HERNÁNDEZ, Castelldefels (ES)

(73) Assignee: Fundacio Centre Tecnologic de Telecomunicacions de Catalunya, Castelldefels (ES)

(21) Appl. No.: 16/322,978

(22) PCT Filed: Aug. 2, 2016
(86) PCT No.: PCT/EP2016/068402

§ 371 Date: Feb. 4, 2019

(30) Foreign Application Priority Data
Aug. 5, 2016 (IN) 201621026847

(51) Int. Cl. H03M 3/00

(52) U.S. Cl. CPC H03M 3/368; H03M 3/496; H03M 3/41; H03M 3/422; H03M 3/40

(57) ABSTRACT

A device, system and method for improvement of analog/digital conversion. An improved delta sigma-converter including a phase or frequency modulation and demodulation, is used. The improved delta sigma-converter obtains higher gains than traditional Delta Sigma converter, preserving or improving the oversampling and noise shaping gains of these converters.

### TECHNICAL FIELD

The present invention relates generally to the field of analog to digital converters, more particularly, deals with an improved delta sigma-converter including a PM/FM non-linear loop which allows to represent a signal with finite dynamic range by a discrete signal using a finite set of amplitude levels, obtaining higher gains than traditional Delta Sigma converter, preserving or improving the oversampling and noise shaping gains of these converters.

### STATE OF THE ART

One of the key problems in representing an analog signal by a discrete signal is the socalled quantization error. Quantization error is motivated by the discretization of the continuous amplitude values in a given period of time by a constant amplitude selected from a given set of values named alphabet. Currently, the basic tools to combat the effects of the quantization error when trying to recover the original analog signal are basically two. The first is oversampling which entails to reduce as much as possible the period of time that the constant amplitude represents the original analog signal. The second is the so-called noiseshaping which basically consists on shaping the spectral content of the quantization error such that it reduces the overlap with the spectral content of the original signal.

When trying to reduce as much as possible the length of the alphabet to just two or three levels, the major contribution has been the delta-sigma converter (known as ΔΣ or DS converter), sometimes described as 1-bit analog to digital converter (or 1-bit ΔΣ). Current commercial systems with ΔΣ technology, fully implanted in the audio industry, achieve that with a single bit, i.e. two amplitude levels, produce the same quality as a traditional converter of 16 bits (65536 levels). The quality is in terms of power of the original signal versus power of the quantization error or noise (the quotient is denoted as the signal to noise ratio of the converter SNRQ). The impact of ΔΣ technology is tremendous and the number of technical papers on the topic is very large. A good paper, widely referenced, with the principles of DS as well as improvements over the original idea is P. M. Aziz, H. V. Sorensen, J. Van der Spiegel. “An overview of Sigma-Delta Converters: How 1-bit ADC achieves more than 16-bit resolution”. IEEE Signal Processing Magazine, Vol. 13, Issue 1, pp. 61-84, September 1996.

Non-linear processing, in general frequency (FM) or phase modulators (PM), has been reported implemented as a pre-processing cascade before the ΔΣ converter. Examples of these converters using FM modulator or Hadamard modulators, can be found for example on M Hovin, A. Olsen, T. Sverre Lande, C. Toumazou. “Delta-Sigma Modulators using Frequency-Modulated Intermediate Values”. IEEE Journal of Solid State Circuits. Vol. 32, No. 1, pp. 13-22, January 1997. None of the existing modification alters the basic loop of the ΔΣ converter.

The basic loop of a DS (ΔΣ) converter is composed of an integrator followed by a quantizer (for example a two-level quantizer with amplitudes+/−A or “mid-tread” or a three levels quantizer with amplitudes 0, +A, −A named “mid-raiser”). The output signal is feedback to the input, such that the difference (Δ—delta) of the original signal minus the feedback output forms the input to the integrator (Σ—sigma). This basic loop implements both oversampling and noise shaping principles in order to produce a discrete version of the original signal. The original signal is recovered by lowpass filtering the discrete version at the output of the ΔΣ converter.

In order to further increase the quality of the basic ΔΣ converter, additional loops can be imbricated in the original scheme. This is referred to as high order ΔΣ converters, where the order reflects the number of feedback loops used or number of “delta” blocks forming the converter. The ΔΣ described in the previous paragraph is denoted as first order ΔΣ or DS converter. High order ΔΣ modulators can also be achieved by cascading first order modulators. Other techniques like time interleaved ΔΣ converters increase also the quality of the first order ΔΣ by setting several order one ΔΣ converters in parallel.

In general, all the architectures reported with order greater than one produce better quality at the expense of sensitivity to implementation imperfections due to the presence of multiples loops in the corresponding architecture. Furthermore, the in-phase/quadrature components structure of a band pass signal has not been fully used to improve the performance of ΔΣ converters.

The basic tools/arguments that provide the goodness of ΔΣ or DS (delta/sigma) converters still remain as the two originals, i.e. oversampling and noise shaping. In all cases found in the literature, the desired signal is not protected against channel noise.

The embodiments of the invention proposed in the present specification below will overcome at least some of the mentioned drawbacks.

### SUMMARY OF INVENTION

The present invention is defined in the attached independent claims. Specific optional embodiments of the invention are defined in the attached dependent claims. The problems found in prior art techniques are generally solved or circumvented, and technical advantages are generally achieved, by the disclosed embodiments which provide a device, system and method for improved delta-sigma conversion.

The present invention is able to represent a signal (a low pass analog signal) with finite dynamic range by a discrete signal using a finite set of amplitude levels, in an improved way. Gains from one bit to five bits, i.e. 15-30 dB of Signal to Noise Ratio (SNR_{Q}) over the gains obtained from a first order, let us say, traditional Delta Sigma converter (ΔΣ or DS) are obtained, yet preserving the oversampling and noise shaping gains of these converters. Aside from achieving a technique of low complexity for analog to digital conversion, the invention provides protection against channel noise, at the same time that it provides significant reduction on the impact of the quantization noise.

More precisely, an object of the invention is to introduce a non-linear instantaneous transformation/modulation in the basic loop of the DS converter. This transformation consists of a Phase Modulator (PM) or a Frequency Modulator (FM), that depending on the modulation index, ϕ_{d} (radians) for PM and f_{d} (Hz). for FM, controls the existing tradeoff between bandwidth of the resulting discrete signal and the SNR_{Q} gain of the converter. The proposed converter will be called from now on: Non-linear delta sigma modulation, NDM. Furthermore, NDMPM will denote a phase modulation transformation and NDMFM a frequency modulation transformation.

The data input for the converter could be for example an analog low-pass band limited signal of bandwidth B Hz, or its sample and hold version, at sampling rate with frequency B_{T} samples per second, being the quotient B_{T}/2B the so-called oversampling ratio.

The main feature of the proposed invention is that the signal after the delta operation, followed by the sigma operation, and usually before entering into the quantizer (also called quantization unit) is modulated in phase or in frequency. This processing is the responsible for the extra gain on quantization noise and channel noise protection.

The PM or FM signal may be generated as in-phase and quadrature components of a selected carrier frequency fc (fc>BT/2). The in-phase component may be formed by the PM/FM modulation of a cosine and the quadrature component may be formed by the same modulation PM/FM of a sine. This allows the use of two quantizers in parallel, which provides in essence a gain of 6 dB over the traditional DS converter with minimum complexity. Furthermore, for 1-bit converter the overall in-phase and quadrature modulation plus the two parallel quantizers can be implemented by a processor that depending on the range of the analog signal after the sigma operation maps on different and discrete phases of the carrier frequency. For example, using 1 bit mid-riser quantizer, depending on the dynamic range of the input signal, the processor maps into four phases or frequencies. Using three levels mid-tread the input signal is mapped into eight different phases or frequencies. This allows direct and very low complexity implementation of the modulation/conversion stage of the invention. The corresponding in-phase and quadrature components, formed as the quantized versions of the cosine and sine, after low pass filtering at B_{T}/2, are applied to an i-q modulator to produce a PM/FM band-pass signal. Note that the low pass filtering is equivalent to the so-called pulse-shaping in digital communications. The proposed converter preserves the rule of 6 dB per bit increase for a number of bits above 2 using mid-raiser or mid-tread quantizers.

In a first aspect, it is proposed a device for analog-to-digital converting of an analog input signal into a digital output signal. The device comprises a Delta-Sigma, DS, converter, the DS converter comprising a subtraction unit (delta unit), an integration unit (sigma unit, which performs an integration/sigma operation), a quantization unit and a delay unit, the device being characterized by further comprising:
A phase modulator, PM, (for phase modulation before obtaining the output signal) in the (main) feed-forward branch (feed-forward branch of the basic loop) of the DS converter and a phase demodulator in the (main) feedback branch (feedback branch of the basic loop) of the DS converter (for phase demodulation before feeding the delta/subtraction unit)
   or
A frequency modulator, FM, (for frequency modulation before obtaining the output signal) in the (main) feed-forward branch (feed-forward branch of the basic loop) of the DS converter and a frequency demodulator in the (main) feedback branch (feedback branch of the basic loop) of the DS converter (for frequency demodulation before feeding the delta/subtraction unit).

The phase modulator or the frequency modulator may be connected in series with the quantization unit and the output of the phase modulator or the frequency modulator may be connected to the input of the quantization unit (the output of the quantization unit will be the digital output signal of the converter).

In an embodiment, the phase modulator or the frequency modulator is connected in series with the subtraction unit, the integration unit and the quantization unit of the DS converter in the following way: the input of the phase modulator or the frequency modulator is connected to the output of the integration unit, the output (or outputs) of the phase modulator or the frequency modulator is connected to the input of the quantization unit and the output of the subtraction unit is connected to the input of the integration unit (the subtraction unit subtract to the input signal, the output of the main feedback branch).

In an embodiment, the input of the phase demodulator or the frequency demodulator is connected to the output of the quantization unit.

In an embodiment, the phase demodulator or the frequency demodulator is connected in series with the delay unit, where the output of the phase demodulator or the frequency demodulator is connected to the input of the delay unit and the output of the delay unit is an input of the subtraction unit.

The device may further comprise a low pass filter. The input of the low pass filter may be connected to the output of the delay unit and the output of the low pass filter may be an input of the subtraction unit

The device may further comprise a sample and hold unit which processes the analog input signal at a selected sampling frequency; the resulting sampled signal will be an input of the subtraction unit of the DS converter (the subtraction unit subtracts to the sampled input signal, the output of the main feedback branch).

The analog input signal may be an audio signal, a video signal and audio-video signal or any type of electronic signal.

The output of the phase modulator or the frequency modulator usually includes an in-phase component and a quadrature component.

In a second aspect, it is proposed a system which comprises the previously described device, that is, a signal processing device for analog-to-digital converting of an analog input signal into a digital output signal. The device comprises a Delta-Sigma, DS, converter, the DS converter comprising a subtraction unit (delta unit), an integration unit (sigma unit, which performs an integration/sigma operation), a quantization unit and a delay unit, the device being characterized by further comprising:
A phase modulator, PM, in the feed-forward branch of the DS converter and a phase demodulator in the feedback branch of the DS converter;
   or
A frequency modulator, FM, in the feed-forward branch of the DS converter and a frequency demodulator in the feedback branch of the DS converter.

This system may be, for example, a transmitter for transmission of audio or video signals which includes the previously described device.

The system may further comprise a pulse shaping or a digital/analog converter, where the output of the device is connected to the input of the pulse shaping or the digital/analog converter.

The system may further comprise and in-phase/quadrature modulator and where the output of the pulse shaping or the digital/analog converter is the input of the in-phase/quadrature modulator. The carrier frequency used by the in-phase/quadrature modulator is usually higher than half of the sampling frequency used to sample the analog input signal.

In an embodiment, the output of the pulse shaping or the digital/analog converter (or the output of the in-phase/quadrature modulator if any) is transmitted through a communications channel. The system may further comprise a receiver (to receive the signal transmitted through the communications channel) comprising a sample and hold unit, a phase demodulator or a frequency demodulator, a digital/analog converter and a low pass filter.

In a third aspect, it is proposed a method for analog-to-digital conversion of an analog input signal into a digital output signal, the method being performed by a device comprising a Delta-Sigma, DS, converter, the DS converter comprising a subtraction unit, an integration unit, a quantization unit and a delay unit, the method being characterized by:
Performing a phase modulation (e.g. of the output of the integration unit) in the (main) feed forward branch on the DS converter and performing a correspondent phase demodulation (e.g of the output of the quantization unit) in the (main) feedback branch of the DS converter or
Performing a frequency modulation (e.g. of the output of the integration unit) in the (main) feed forward branch on the DS converter and performing a correspondent frequency demodulation (e.g of the output of the quantization unit) in the (main) feedback branch of the DS converter.

According to another aspect of the invention, a computer program product is provided, comprising computer-executable instructions for performing any of the method previously disclosed, when the program is run on a computer and a non-transitory digital data storage medium is also provided encoding a machine-executable program of instructions to perform any of the methods disclosed.

Consequently, according to the invention, a device, method, system, a computer program and a data storage medium according to the independent claims are provided. Favorable embodiments are defined in the dependent claims.

These and other aspects of the invention will be apparent from and elucidated with reference to the embodiments described hereinafter.

### BRIEF DESCRIPTION OF THE DRAWINGS

To complete the description and in order to provide for a better understanding of the invention, a set of drawings is provided. Said drawings form an integral part of the description and illustrate a preferred embodiment of the invention, which should not be interpreted as restricting the scope of the invention, but just as an example of how the invention can be embodied. The drawings comprise the following figures:

FIG. 1 shows a block diagram of a system which uses the NDM converter according to an embodiment of the invention.

FIG. 2 shows a block diagram of a system which uses the NDM converter, with a phase (NDM-PM) or frequency (NDM-FM) modulator, according to an embodiment of the invention.

FIG. 3 shows (top part) the power spectrum density of the resulting signal of a NDM converter using phase modulation, according to an embodiment of the invention, in a particular scenario. In the bottom part, FIG. 3 shows, the corresponding power spectrum in the same scenario for a prior art DS converter.

FIG. 4 shows the power spectrum density of the resulting signal of a NDM converter using frequency modulation according to an embodiment of the invention, in the same scenario used in FIG. 3.

FIGS. 5A, 5B and 5C show the power spectrum density of the conversion noise for a NDM-PM converter (5A), NDM-FM converter (5B) and a prior art DS converter (5C), corresponding to the scenario and parameter settings used in FIGS. 3 and 4.

### DETAILED DESCRIPTION OF THE INVENTION

The present invention may be embodied in other specific devices, systems and/or methods. The described embodiments are to be considered in all respects as only illustrative and not restrictive. In particular, the scope of the invention is indicated by the appended claims rather than by the description and figures herein. All changes that come within the meaning and range of equivalency of the claims are to be embraced within their scope.

As an example, here below a practical implementation of the invention is described for a generic low pass signal x(n) (produced as a sample/hold version of an analog signal x(t) as it will be explained later). The sample period may be normalized, for the sake of clarity of the presentation, at one.

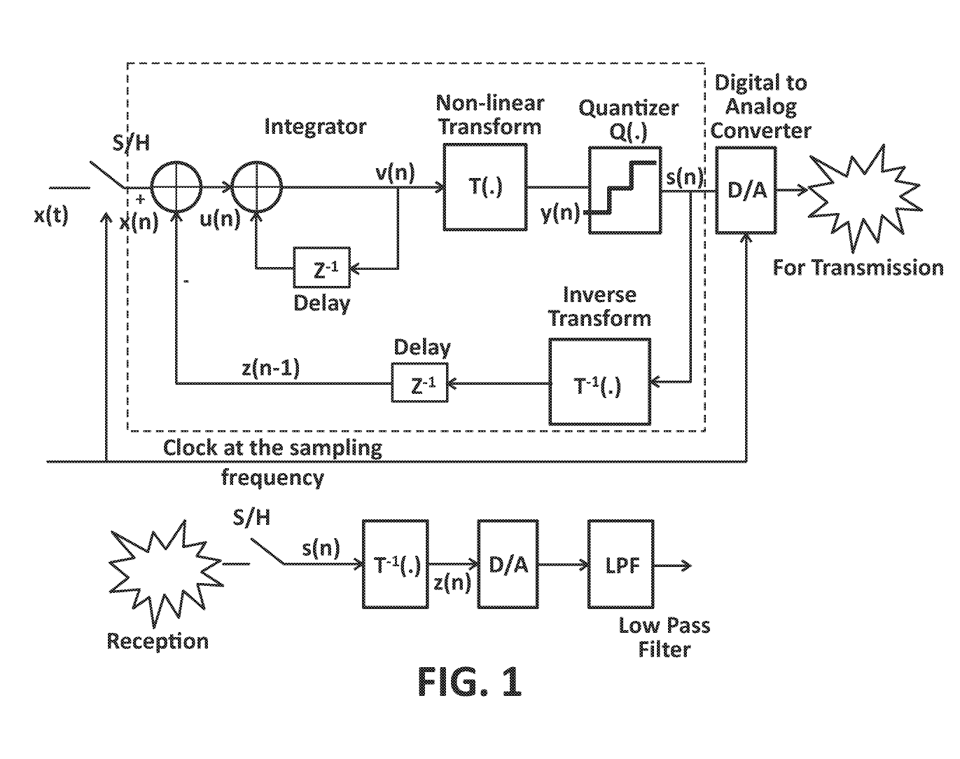

FIG. 1 shows a general block diagram of a system which uses the NDM converter according to an embodiment of the invention. The NDM converter mainly comprises the elements included in the dotted lines frame. The input signal x(t) maybe any signal, for example, an electronic signal, an audio or video signal of any other type of signal. In this example, the signal input in the delta-sigma converter, x(n), is assumed to be a sampled/hold version of the analog signal; the dynamic range of the input signal is assumed normalized in the range (−1,1) mV (this is only an example, for clarity, simplicity and explanation purposes). That is, the input analog signal x(t) is applied to a sampled/hold unit (S/H) at a sampling frequency; this sampling frequency may be far above the Nyquist rate in order to produce an oversampled version of the analog signal. As it can be seen from FIG. 1, the delta (also called subtraction) operation is performed subtracting from the input signal x(n) the previous value of the signal z(n) in the lower branch (also called feedback branch or feedback loop). The resulting difference signal, u(n), goes through the sigma operation, which may be performed by a first order integrator (also called integration unit), producing a signal v(n). This integration function in his simplest version may consist on adding the input of the integrator with a delayed version of the output of the integrator (of course, any other more complex integrator may also be used). Signal v(n) is transformed by transform T(.) into y(n) (as it will be later explain, this transform T may be a non-linear transform and, more particularly, it may be a phase modulation or a frequency modulation). Then y(n) is quantized, obtaining the output signal of the converter, s(n) (the quantized version of y(n), representing the quantizer function by Q(.)). The quantizer may be for example a mid-riser or a mid-tread quantizer. The output signal s(n) after inverse transform (T⁻¹(.) and delay (Z⁻¹) is feedback in the lower branch (feedback branch or feedback loop) for the delta operation.

There is not need for a digital to analog converter in the feedback branch as the quantized signal is a discrete signal which can be subtracted (after inverse transform) from the input signal x(n) (in the delta operation) directly.

Note that with respect to the traditional Delta Sigma converter the invention introduces a transformation in the upper branch as well as the inverse transform in the lower branch. In addition, note that the recovered waveform may be a low pass filtered version of z(n) (this low pass filter is not depicted in the figure). Usually, before using the output s(n) of the Delta Sigma Converter (for example for recording or for being transmitted in a communication channel) said signal goes to a D/A converter or pulse shaping. For recovering a replica of the original signal x(t), (e.g. in reception, when receiving the signal transmitted through the communication channel), the reception signal may be passed through a sample and hold unit, an inverse transformation (of the transformation made in the NDM converter), followed by a D/A converter, followed by an analog low pass filter. This is shown in the bottom part of FIG. 1.

In FIG. 1 the modified Delta-Sigma converted (NDM converter) proposed, comprises the main signal processing part (dotted rectangle). The rest of the processing, i.e. sample and hold, D/A converter, low pass filter . . . , are elements which do not purely belong to the converter, so they will be not further considered (as they are out of the object of the present invention). In addition, in order to compute the signal to noise ratio of the NDM converter, note that a digital low pass filter version of z(n) may provide the recovered signal, i.e. a replica of the input x(n).

As it has been stated, for simplicity and explanation purposes, it has been supposed that the signal input in the delta-sigma converter, is a sampled/hold version (x(n)) of an analog signal. In the case, that an analog input x(t) is applied directly to the NDM converter (without sampling and hold at the beginning), the sample and hold can be set at the quantizer (becoming a sort of “analog version” of the NDM shown in FIG. 1).

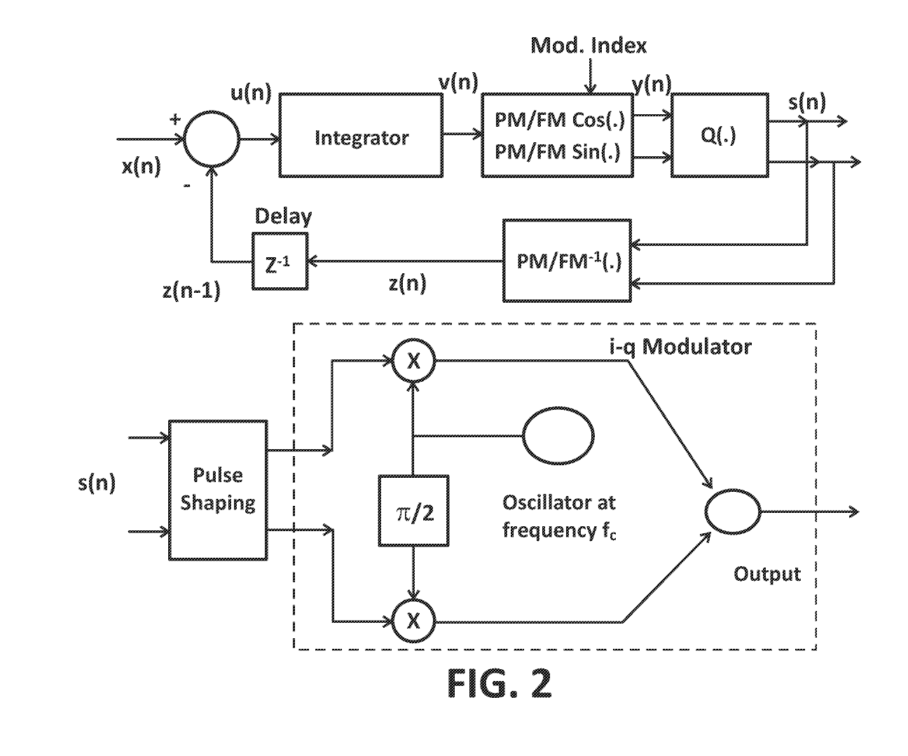

FIG. 2 shows a preferred embodiment of the present invention, where the transform T used in the converter, is a phase (NDM-PM) or frequency (NDM-FM) modulation. That is, FIG. 2 shows a particular case of the system shown in FIG. 1 where a PM or FM modulator and demodulator is used in the proposed NDM converter. The PM or FM modulator will be situated in the main feed-forward branch (also called direct branch, feedforward branch or upper branch) of the DS converter, that is, in series with the integrator and the quantizer (quantization unit). The correspondent (PM or FM) demodulator is used in the main feedback branch (also called feedback loop), that is in series with the delay unit (Z⁻¹) which will feed the delta/subtraction operator. Note that the band-pass nature of these modulations requires to modulate both an in phase component as cosine and a quadrature component as sine function respectively (that's why in FIG. 2, there are shown two outputs of the PM or FM modulation, as the phase and quadrature component of a complex signal y(n)). This processing will be denoted hereafter as Cos(.) and Sin(.). The resulting signals are quantized producing a complex (two component) signal s(n) that after demodulation (and delay) is used for the feedback as in the previous figure. As stated for FIG. 1, before using the output s(n) of the Delta Sigma Converter (for example for recording or for being transmitted in a communication channel wired or wireless), said signal may go to a D/A converter or pulse shaping (in case of FIG. 2 a pulse shaping is shown). After this pulse shaping, the i-q components are usually processed at a carrier frequency f_{c} by an i-q modulator. The pulse shaping sets the bandwidth of transmission and the i-q modulator sets the central frequency or carrier of the transmission. Note that the waveform at the output of the i-q modulator will be like a digital phase or frequency modulation, i.e. similar to a PSK or FSK digital modulation.

This produces, for each mixer or multiplier, within the i-q modulator, the in-phase and quadrature components of an analog signal at the carrier frequency (cos(2πf_{c}t) and sin(2πf_{c}t)).

The particular arrangement shown in FIGS. 1 and 2 are only examples; the order and location of the elements (delta operation, integrator, non linear transform, quantizer . . . ) shown in said figures is not mandatory. That is, said elements can be arranged in other ways (different locations and order) in the system converter proposed by the present invention (for example the inverse transform can be situated after the delay . . . ). The main feature is that the non-linear transform (PM or FM modulator) is in the feed-forward branch (in series with the integrator and the quantizer) and the correspondent inverse transfer (PM or FM demodulator) is in the feedback branch of the converter. In order to be more clear (and to avoid any misunderstanding, as in the DS converter there may be more than one feed-forward and feedback branches), it can be said that the PM or FM modulator will be situated in the feed-forward branch of the basic loop of the DS converter (also called main feed-forward branch), that is, in series with the integrator and the quantizer. The correspondent (PM or FM) demodulator will be located in the feedback branch of the basic loop (also called main feedback branch), that is in series with the delay unit (Z⁻¹) which will feed the delta/subtraction operator. As in a DS converter there can be other secondary loops (for example in the integrator), the expression “basic loop” is used to refer to the main loop of the DS converter, that is the loop formed in its feedforward branch by the delta (subtraction) operation, the sigma (integrator) operation and the quantizer (and the non-linear transformation in case of NDM converters) and in its feedback branch formed by the delay unit (Z⁻¹) which feeds the delta operation (and the non-linear inverse transformation in case of NDM converters).

Of course the demodulator in the feedback branch of the basic loop should be the corresponding demodulator to the modulator (FM or PM) used in the feed-forward branch of the basic loop, that is, it must perform the inverse function of the modulation performed by the modulator (so it usually uses the corresponding same parameters and coefficients than the modulator).

Now the particular operation of the NDM converter, using the arrangement shown in FIG. 2, will be explained with more detail:

The delta operation produces signal u(n) as the difference between the input signal x(n) and the previous sample of z(n) (in FIGS. 1 and 2, the expression Z⁻¹ is used to denote an operation in which a signal is delayed one sample)

u(n)=x(n)−z(n−1)

The sigma (integration) operation is implemented by an integrator that produces v(n) as:

v(n)=v(n−1)+u(n) or v(n)−v(n−1)=u(n)=x(n)−z(n−1)

For PM modulation (NDM-PM), the modulator forms the in-phase and quadrature components of v(n) as follows, where φ_{d} is the phase modulation index.

cos(φ_{d}v(n))

sin(φ_{d}v(n))

For FM modulation (NDM-FM), v(n) is integrated and the resulting signal vfm(n) (vfm(n)=vfm(n−1)+v(n)) modulates the in phase and quadrature components as it is shown below, where f_{d} is the frequency modulation index.

cos(2πf_{d}vfm(n))

sin(2πf_{d}vfm(n))

The pair of in-phase and quadrature components can be represented as the real and imaginary parts of the following complex signal y(n) for PM (Phase Modulation) and FM (Frequency Modulation) respectively.

y(n)=PM(v(n))=exp(jφ_{d}v(n)) or y(n)=FM(v(n))=exp(j2πf_{d}vfm(n))

For simplicity purposes, without loss of generality the case in which PM modulation is used (NDM-PM) will be explained from now on (the same explanation will be valid, mutatis mutandis, to the NDM-FM case). As before was shown that v(n)−v(n−1)=x(n)−z(n−1), the following expression in the NDM-PM is valid:

PM(v(n)−v(n−1))=PM(x(n)−z(n−1))

As the exponential function converts sum in a product and subtraction in a quotient, (both for PM and FM), then it follows that:

PM(v(n))/PM(v(n−1))=PM(x(n))/PM(z(n−1))

Taking into account the expression of y(n)=PM(v(n)), the following result is obtained:

y(n)/y(n−1)=PM(x(n))/PM(z(n−1))

After the quantizer, the signal s(n), considering the quantizer as an additive noise source with complex value w(n), may be formulated as:

s(n)=y(n)+w(n) or y(n)=s(n)−w(n)

Note that the previous equations imply that the quantizer is linearized. In other words, it is assumed that the quantization noise is independent of the input value. This is not formally correct for low numbers of quantization levels. Nevertheless, linearizing the quantizer provides light into the resulting performance of the converter (even for low number of levels when the independence claimed is not totally correct), so said assumption is going to be used as it leads to valid results about the converter performance.

Substituting this in the above formula of y(n), it is obtained a relationship between the output of the NDM-PM s(n) and the input x(n).

(s(n)−w(n))/(s(n−1)−w(n−1))=PM(x(n))/PM(z(n−1))

In addition, since z(n) is the PM inverse of s(n), that is, z(n)=PM⁻¹(s(n)), so PM(z(n))=PM(PM⁻¹(s(n)))=s(n). Using this in the above formula, the following final expression is obtained:

s(n)−w(n)=(s(n−1)−w(n−1))PM(x(n))/s(n−1) or

s(n)=PM(x(n))+w(n)−((PM(x(n))/s(n−1))w(n−1))

It can be shown that this expression remains the same for the FM modulator just changing function PM(.) by FM(.). That is, when using FM modulation:

s(n)=FM(x(n))+w(n)−((FM(x(n))/s(n−1))w(n−1))

Thus s(n) is a discrete version of a phase modulation or frequency modulation of the original input signal plus a noise factor (this noise factor will be w(n)−((PM(x(n))/s(n−1))w(n−1)) for PM modulation or w(n)−((FM(x(n))/s(n−1))w(n−1)) for FM modulation). This noise suffers the desired noise shaping, i.e. loaded to high frequency due to the minus sign affecting the one sample delayed version of it. The difference in the shaping is that this factor multiplying w(n−1) is one for DS and in the present invention the delayed noise sample is multiplied by the quotient between the desired signal of s(n), i.e. the PM or FM version of the input x(n), divided by the previous output s(n−1). Clearly under low noise regime and high oversampling factor (SNR_{Q} greater than 30 dB and r>5, where r=log₂(B_{T}/2B), being r the oversampling gain) shaping becomes almost identical to the obtained on the traditional ΔΣ modulator.

It is worthwhile to mention that the phase modulation step (the implementation of the phase modulation), i.e. passing from the output of the integrator to the output s(n), can be done directly from the use of a look-up table which resumes the PM modulation and the quantizer. This reduces greatly the complexity of the modulator whenever the number of levels is small, i.e. two or three levels quantizers. This applies also for the demodulation embedded in the lower branch. In fact the look at table passes directly from the input of the modulator to the reconstructed phase values at the lower branch.

Under this model the performance of the NDM versus DS will increase due to the modulation. For PM the gain will be close to 20 log₁₀(φ_{d}) dB, which will be close to 10 dB for φ_{d} equal to its maximum value of π (i.e. no ambiguity in the phase load), and for FM will be close to 10 log₁₀(3(f_{d}/B)²), where B is the bandwidth of the original low pass input signal.

Note that, for a given number of bits for each quantizer the number of levels used is twice of the traditional DS converter since there are two quantizers, one for the phase component and another one for the quadrature component, acting in parallel. For a number of bits in the quantizers greater than 2 (i.e. more than 3 levels per quantizer) this amounts for an extra gain of 6 dB due to the fact that the number of levels used in NDM is twice the number of levels used in DS. For the case of 1 bit, the quantization noises and original signal are correlated and no significant gain should be expected due to the use of two quantizers in parallel in this respect.

Using these values, an increase of 9.94 dB for NDM-PM (φ_{d}=TO and 34 for NDM-FM (modulation index f_{d}=0.2, B_{3d}B=0.0039 of the input sigma) improvement versus DS can be expected plus the extra bit due to the use of two quantizers in parallel. Using a sinusoid at frequency 0.002 (all frequencies are normalized by the sampling frequency) as input signal, the resulting SNRs are shown below.

The SNR_{Q} for DS may be calculated using the following prior-art formula (see for example Dave Van Ess, “Signal from Noise: Calculating Delta-Sigma SNRs”. EN-Genius Network. www.en-genius.net), which provides the SNR_{Q} of the DS for different order L and oversampling factor n.

SNR_{Q}^{DS} (dB.)=3.01n(2L+1)−9.36L−2.76

For order one (L=1) and oversampling factor of approx. 7 (i.e. log₂(B_{T}/2B)=log₂(1/(2*0.0039)), the resulting SNR is 50.95 dB.

The following table shows the gains in dB of the converters. It is denoted as “Expected” the estimates mentioned before of 9.94 for NDM-PM and 34 for NDM-FM as the modulation gains, plus the fix gains that the converter has. Also the loss of 9.36 and 2.76 for the DS modulator (see formula above) are not present for the NDM converter.

| | DS 1 bit | NDM-PM 1 bit | NDM-FM(mid-tread) |
|---|---|---|---|
| Measured | 51 dB | 77.12 dB | 107.52 dB |
| Measured - | reference | 26.12 dB | 56.52 dB |
| DS (51 dB) | | | |
| Expected | reference | 9.94 + 12.12 + 6 = | 34 + 12.12 + 12 = |
| | | 28.06 dB | 58.12 dB |

Note that regardless the severe approximations the NDM expected gains (last file of the table), due to angle modulation, and the measured gains are very close.

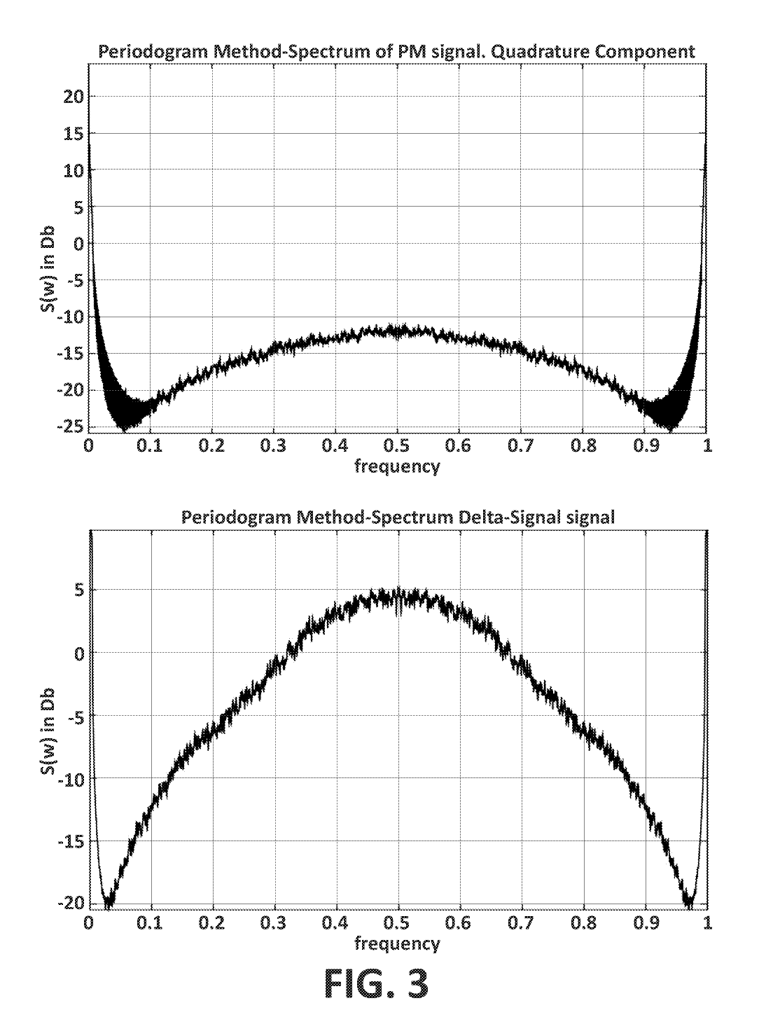

The top part of FIG. 3 shows the power spectrum density of the resulting signal s(n) of the NDM converter (NDM-PM converter) in a particular case. For the result shown in FIG. 3, the power spectrum density is computed from the average of periodograms of records of 256 samples of the output signal s(n), for the quadrature component only (the power spectrum density for the phase component will be the same). The record length was 10⁵ samples. The input signal is noise of uniform distribution filtered at 0.0039 (3 dB bandwidth). The dynamic range of the signal is +/−1 mV. The parameters used in the converter have been: A PM modulator with modulation index φ_{d} equal to π (maximum phase deviation), carrier amplitude 1 volt, sampling rate normalized to one (T=1), 1 bit mid-riser quantizer of 2 levels for both in-phase and quadrature components. The decision levels of the quantizer were +/−0.5 mV. The input signal was white noise with a FIR of 512 coefficients with a bandwidth B of equal to 0.0039. The plot set the averaged periodogram in dB versus the frequency between zero and the sampling frequency equal to 1 (symmetric with respect half the sampling frequency) The resolution of the frequency plot is 9.76 10⁻⁵.

In the bottom part of FIG. 3, the corresponding power spectrum for a prior art DS converter with 1-bit mid-riser 2 levels quantizer is shown.

Note that the noise shaping is well present in both converters. This effect is masked partially for NDM-PM due to the high spectral dynamic range of the PM signal. Note that the power of output signal is the same in DS and NDM converters, in consequence the area of both spectral densities are the same. Of course, the selected carrier frequency does not affect the final SNR_{Q} quality of the converter since, at the receiver site, the PM detector extracts the unwrapped carrier phase.

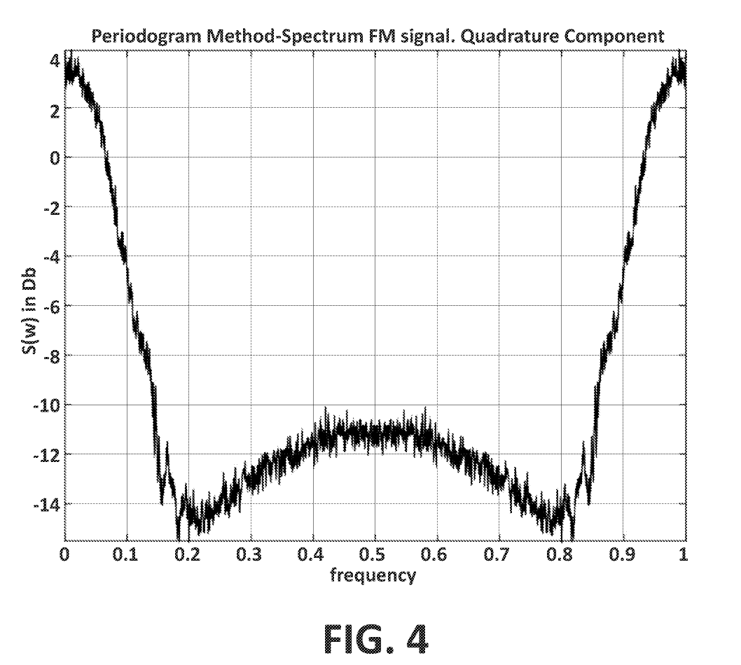

FIG. 4 shows the power spectrum density of the resulting signal of a NDM converter (NDM-FM converter), i.e. the case of using an FM modulator. The parameters set is the same that in FIG. 3. The only difference is the modulation index f_{d}, which in this figure is 0.2. The quantizers used were mid-tread. Note that in addition to the wideband nature of FM the shaping is still preserved in the quantization noise.

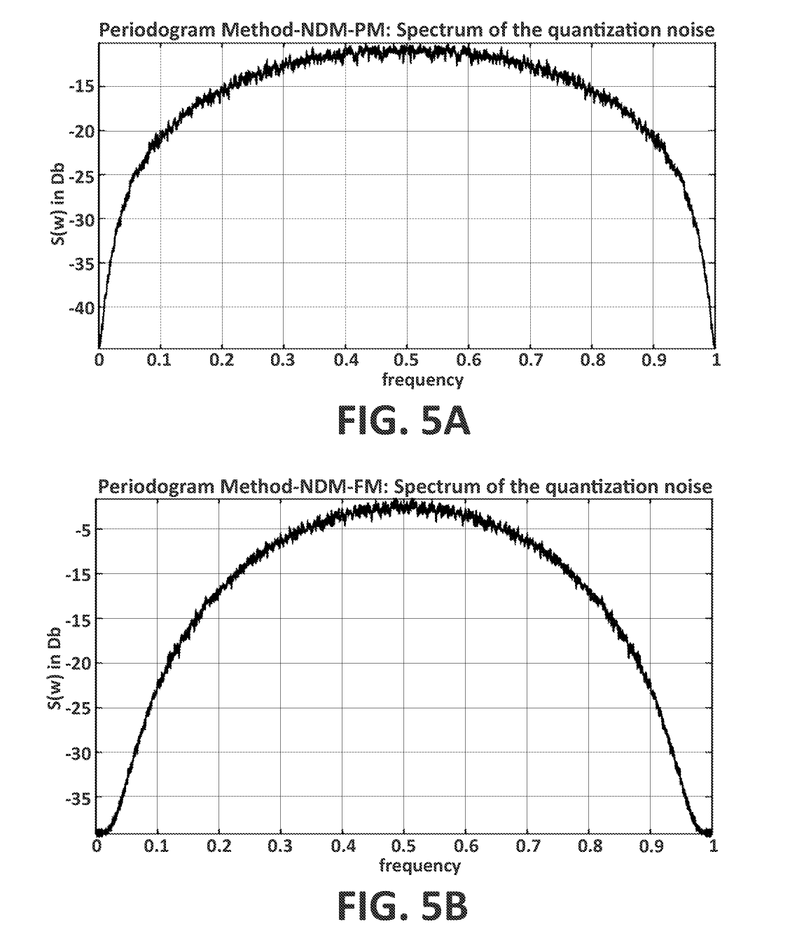

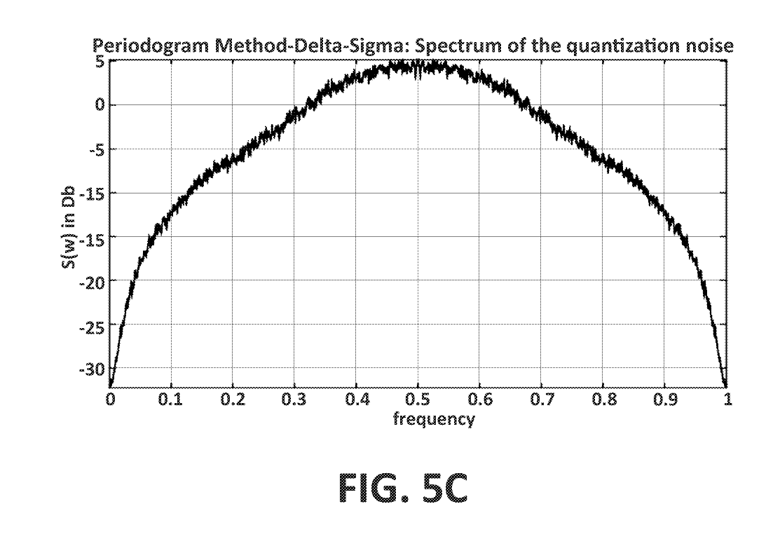

FIG. 5 shows the power spectrum density of the quantization noise for a NDM-PM converter (5A), NDM-FM converter (5B) and a prior art DS converter (5C) corresponding to the scenario and parameter settings used in previous figures. The quantization noise is measured here as the difference between the input signal x(n) and the feedback signal z(n) taking into account all the existing delays within the loop, so even it is called “quantization” noise, it is more a conversion “noise” as it is the noise introduced by the conversion. Note that the noise floor at low frequencies, where the input signal is located, is lower in NDM-PM than in DS and, for the case of NDM-FM is also low and flat exhibiting a behavior similar to the order two DS (not depicted here). This is due to the inherent double integration at the upper branch of the NDM-FM caused by the FM modulator.

Now some general considerations about the proposed converter, as well as, some examples of the improvement obtained with the proposed converter in different scenarios are going to be explained:

The I-Q Modulator: As stated in FIG. 2, before using the output s(n) of the Delta Sigma Converter, said signal may go to a D/A converter or pulse shaping and then through an I-Q modulator. As PM and FM are modulations intrinsically of band pass nature, this modulator is usually required. Since the inphase and quadrature are done in the low pass NDM loop (top of FIG. 2), this represents that two streams are representing the original signal after the loop. The i-q modulator, previous pulse shaping, put together at the output these two streams in a single band-pass analog signal. Note that this modulation is usually done at a frequency fc greater than half of the sampling frequency. The PM-FM modulations at central frequencies (f_{c}) above half of the sampling frequency (in wireless transmission usually far above) allows to resume in a single signal the two signals (in-phase and quadrature) coming up from the NDM loop.

FM and the threshold effect: In frequency modulation for low SNR, there is a threshold effect well described in prior art literature. Basically, the effect is motivated by the use of a high modulation index f_{d} (in consequence large detection bandwidths). This threshold effect appears as peaks or glitches when detecting the instantaneous frequency that degrade the recovered SNR. This causes for example that using a mid-tread (2 levels) quantizer for 1-bit NDM-FM converter presents lower SNR than expected due to the threshold effect. For NDM-PM there is not threshold effect for the oversampling ratio used in the figures independently of the number of levels of the quantizer. To overpass the threshold effect, as it is the case of NDM-FM, 1-bit mid-riser for the signal scenario should be selected, otherwise it would be necessary a phase locked loop (PLL) which reduces the processing bandwidth and restores the SNR of the converter. In other words, when working with high modulation indexes, to avoid the necessity of using a PLL device (which will imply an increase of complexity), the levels of the quantizer should be increased (for example, increasing one level (mid-riser) the quantizer (mid-tread).

NDM Line Signal: The line signal or output of the NDM-PM converter for a two levels quantizer, is in fact a 4 PSK (Phase Shift Keying) modulation with phases equal to ±π/4, ±3π/4. And the NDM-FM line signal is like a DPSK (differential PSK) over the previous four-point constellation of phases. Note that for the mid-tread (3 levels) quantizer the constellations of phases pass to be ±π/8, ±3π/8, ±5π/8, 7π/8. In other words a 8PSK (constellation of 8 phases) signal. In consequence, the NDM-PM innovation can be encompassed as a device converting an analog signal directly to a digital band-pass PSK modulation.

High order NDM converters: High order NDM can be implemented by the addition to the NDM of traditional extra delta-sigma loops. The gains obtained are shown below for the following scenario:

| Scenario | Sampling period T normalized to 1 (f_{sampling} = 1) | |
|---|---|---|
| | Original signal: | sinusoid frequency 0.002 |
| | | 3 dB-bandwidth set to 0.0039 |
| | | Dynamic range: (−1, 1) mV. |
| | Quantizers | mid-riser for DS, mid-tread |
| | | for NDM-FM and |
| | | mid-riser for NDM-PM |
| | NDM-PM | Modulation index π radians |
| | SNR | Signal to noise ratio at the output |

| Number of bits | SNR DS (order 2) | NDM-PM (order 2) |
|---|---|---|
| 1 | 84.23 dB | 115.16 dB |
| | | (Mid-tread converter) |
| 2 | 92.58 dB | 117.42 dB |
| 3 | 96.65 dB | 124.16 dB |
| 4 | 98.03 dB | 129.93 dB |

Performance order 1 converters above 1 bit:

Scenario The same used in the previous item.

| Number of bits | NDM-PM | NDM-FM |
|---|---|---|
| 2 | 79.11 dB | 109.67 dB |
| 3 | 90.14 dB | 115.72 dB |
| 4 | 86.53 dB | 127.02 dB |
| 5 | 103.20 dB | 133.14 dB |

It is worth to mention that NDM-FM performs similar to NDM-PM (φ_{d}=π) when the FM modulator uses an index equal to 0.025. Note that NDM-FM entails the use of two integrators, i.e. one of the loop and another in the modulator, as well as NDM-PM of order two. Amazingly NDM-PM of order two provides better SNR_{Q} than NDM-FM of order one. It is important to mention that NDM-PM entails a narrow band modulation meanwhile NDM-FM is wideband without taking full advantage of the noise shaping. In addition, it should be mentioned that the receiver for FM is simpler than for PM, furthermore the receiver for FM can be fully analog and un-coherent.

Some of the advantages of the converter proposed by the present invention are, for example:
High dynamics (50-100 dB) obtained by low bit converters are currently fully installed on audio signal sensing and distribution. In addition to the high dynamics, the major innovation of the invention relies on the ability to convert directly a time continuous signal, or a sample/hold version of it, in a constant envelope digital modulated waveform. The resulting waveform is a constant envelope carrier modulated either in phase or frequency (PSK or FSK). This implies that the converter implements a source coding or representation in terms of a finite set of phases in the i/q (in-phase and quadrature) components of a pre-selected carrier frequency, i.e. channel coding. This enables to interchange between communications nodes high dynamic range signals and, at the same time, providing protection against radio-channel noise of the coded signal.
The impact, especially in Internet of Things (IoT) networks, is very high since the sensing part is almost independent of the corresponding RF part with the corresponding limitations in performance. In addition, the invention represents a way out to the, let us say, traditional, low dynamic and low bandwidth that ambient sensors use to handle.
The proposed converter represents an innovation impacting the wireless and wired sensor production from distributed acoustic processing down to ambient sensing.
The NDM-FM converter can produce narrowband Frequency Modulation enabling the converter to work with a wide range of transmission bandwidths for the desired signal.
The angle modulations embedded in NDM converters protects the NDM converted signal from channel noise, whenever the phase/frequency detector stays above the threshold effect.
The increase in the power of the line signal, PM/FM modulated, produces greater protection to channel noise than linear modulations.
The i-q components in the proposed NDM converter are quantized independently allowing either the arrangement in a single carrier or the time multiplexing of the two streams, yet preserving its superiority with respect to traditional DS converter (double oversampling factor).
The NDM converter can be easily extended to high order modulators NDM-PM and NDM/FM.
NDM-PM modulators of order n+1 are better than NDM-FM of order n, with slightly lower complexity than NDM-FM. At the same time the spectral bandwidth of NDM-PM desired signal shows better spectrum confinement for the desired that NDM-FM.
The NDM converter implements a joint source channel coding that converts a baseband analog signal in a high rate digital phase modulation (QPSK or 8PSK for 1 bit per quantizer).

The different elements (units) cited as part of the proposed NDM converter may be signal processing units (or devices), computing devices or any other type of electronic devices with performs the corresponding function. This is valid, for example, for the element which performs the subtraction (delta) operation (called for example subtraction unit), the element which performs the integration (sigma) operation or function (called integration unit or integrator), the element which performs the quantization operation or function (called quantization unit or quantizer), the element which performs the sample and hold operation or function, the element which performs the delay operation or function (called delay unit), the modulator, the demodulator, the filters or any other element.

The presented embodiments may be embodied in other specific devices, systems and/or methods. The described embodiments are to be considered in all respects as only illustrative and not restrictive. In particular, the scope of the invention is indicated by the appended claims rather than by the description and figures herein. All changes that come within the meaning and range of equivalency of the claims are to be embraced within their scope

A person of skill in the art would readily recognize that steps of various above-described methods can be performed by programmed computers. Herein, some embodiments are also intended to cover program storage devices, e.g., digital data storage media, which are machine or computer readable and encode machine-executable or computer-executable programs of instructions, wherein said instructions perform some or all of the steps of said above-described methods. The program storage devices may be, e.g., digital memories, magnetic storage media such as a magnetic disks and magnetic tapes, hard drives, or optically readable digital data storage media. The embodiments are also intended to cover computers programmed to perform said steps of the above-described methods.

The description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for pedagogical purposes to aid the reader in understanding the principles of the invention and the concepts contributed by the inventor(s) to furthering the art, and are to be construed as being without limitation to such specifically recited examples and conditions. Moreover, all statements herein reciting principles, aspects, and embodiments of the invention, as well as specific examples thereof, are intended to encompass equivalents thereof.

The functions of the various elements shown in the figures, including any functional blocks titled as “processors”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non volatile storage. Other hardware, conventional and/or custom, may also be included. Similarly, any switches shown in the figures are conceptual only. Their function may be carried out through the operation of program logic, through dedicated logic, through the interaction of program control and dedicated logic, or even manually, the particular technique being selectable by the implementer as more specifically understood from the context.

It should be appreciated by those skilled in the art that any block diagrams herein represent conceptual views of illustrative circuitry embodying the principles of the invention. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

1. A signal processing device for non-linear analog-to-digital converting of an analog input signal into a digital output signal, comprising a Delta-Sigma, DS, converter, the DS converter comprising a subtraction unit, an integration unit, a quantization unit and a delay unit, the device comprises:
a phase modulator, PM, in the feed-forward branch of the DS converter for performing phase modulation of either the signal integrated by the integration unit or the signal quantized by the quantization unit, and a phase demodulator in series with the delay unit in the feedback branch of the DS converter, where the phase demodulator is the corresponding demodulator to the phase modulator, performing the inverse function of the modulation performed by the phase modulator in the feed-forward branch or
a frequency modulator, FM, in the feed-forward branch of the DS converter for performing frequency modulation of either the signal integrated by the integration unit or the signal quantized by the quantization unit, and a frequency demodulator in series with the delay unit in the feedback branch of the DS converter, where the frequency demodulator is the corresponding demodulator to the frequency modulator, performing the inverse function of the modulation performed by the frequency modulator in the feed-forward branch.

2. The device according to claim 1 where the phase modulator or the frequency modulator is connected in series with the quantization unit and where the output of the phase modulator or the frequency modulator is connected to the input of the quantization unit and where the output of the quantization unit is the digital output signal of the device.

3. The device according to claim 1, where the phase modulator or the frequency modulator is connected in series with the integration unit and where the input of the phase modulator or the frequency modulator is connected to the output of the integration unit.

4. The device according to claim 1, where the phase modulator or the frequency modulator is connected in series with the subtraction unit, the integration unit and the quantization unit of the DS converter and where the input of the phase modulator or the frequency modulator is connected to the output of the integration unit, the output of the phase modulator or the frequency modulator is connected to the input of the quantization unit and where the output of the subtraction unit is connected to the input of the integration unit.

5. The device according to claim 1, where the input of the phase demodulator or the frequency demodulator is connected to the output of the quantization unit.

6. The device according to claim 1, where the output of the phase demodulator or the frequency demodulator is connected to the input of the delay unit and the output of the delay unit is the input of a subtraction unit.

7. The device according to claim 1, where the device further comprises a low pass filter, where the output of the phase demodulator or the frequency demodulator is connected to the input of the delay unit, where the input of the low pass filter is connected to the output of the delay unit and where the output of the low pass filter is an input of the subtraction unit.

8. The device according to claim 1, the device further comprising a sample and hold unit which processes the analog input signal at a selected sampling frequency and where the resulting sampled signal is an input of the subtraction unit of the DS converter.

9. The device according to claim 1, where the analog input signal is an audio signal, a video signal and audio-video signal or any type of electronic signal.

10. The device according to claim 1, where the output of the phase modulator or the frequency modulator includes an in-phase component and a quadrature component.

11. A system which comprises a device according to claim 1, the system further comprising a pulse shaping or a digital/analog converter and where the output of the device is connected to the input of the pulse shaping or the digital/analog converter.

12. A system according to claim 11, the system further comprising and in-phase/quadrature modulator and where the output of the pulse shaping or the digital/analog converter is the input of the in-phase/quadrature modulator.

13. A system according to claim 11, where the output of the pulse shaping or the digital/analog converter is transmitted through a communications channel, the system further comprising a receiver comprising a sample and hold unit, a phase modulator or a frequency demodulator, a digital/analog converter and a low pass filter.

14. A method for non-linear analog-to-digital conversion of an analog input signal into a digital output signal, the method being performed by a device comprising a Delta-Sigma, DS, converter, the DS converter comprising a subtraction unit, an integration unit, a quantization unit and a delay unit, the method comprises:
performing a phase modulation in the feed forward branch on the DS converter of either the signal integrated by the integration unit or the signal quantized by the quantization unit, and performing a phase demodulation, by a phase demodulator in series with the delay unit, in the feedback branch of the DS converter, where the phase demodulation is the corresponding demodulation to the phase modulation, performing the inverse function of the phase modulation of the feed-forward branch or
performing a frequency modulation in the feed forward branch on the DS converter of either the signal integrated by the integration unit or the signal quantized by the quantization unit, and performing a frequency demodulation, by a frequency demodulator in series with the delay unit, in the feedback branch of the DS converter, where the frequency demodulation is the corresponding demodulation to the frequency modulation, performing the inverse function of the frequency modulation of the feed-forward branch.

15. A non-transitory digital data storage medium encoding a machine-executable program of instructions to perform a method according to claim 14.
